(19) United States
(12) Patent Application Publication
(10) Pub. No.: US 2012/0067610 A1
(43) Pub. Date: Mar. 22, 2012

(54) ELECTRICAL SAFETY COVER

(76) Inventors: Michael T. Stonebraker, Chesterfield, VA (US); Stephen E. Stonebraker, Malvern, OH (US)

(21) Appl. No.: 13/235,977

(22) Filed: Sep. 19, 2011

Related U.S. Application Data
(60) Provisional application No. 61/384,550, filed on Sep. 20, 2010.

(51) Int. Cl. H05K 5/00; H05K 13/00

(52) U.S. Cl. 174/50; 174/520; 29/592.1

(57) ABSTRACT

A system, apparatus and method for protecting electrical boxes while allowing an electrical system to be energized is presented. An electrical safety cover includes a box-shaped base and a door. The box-shaped base is adapted to be attached to an electrical device mounted in an electrical box in place of a cover of the electrical box. The base covers wire connection points in the electrical box preventing touching of exposed metal wire and other metal that carries electricity. The base forms a chamber to allow access to a control, switch or outlet located in the electrical box. The door is movable between open and closed positions. Placing the electrical safety cover in the open position allows access to the control, switch or outlet located in the electrical box, wherein the closed position protects the electrical box.

### CROSS REFERENCE TO RELATED APPLICATION

This application claims priority from U.S. Provisional Application Ser. No. 61/384,550 filed Sep. 20, 2010; the disclosure of which is incorporated herein by reference.

### BACKGROUND OF THE INVENTION

1. Technical Field

The current invention relates generally to apparatus, systems and methods for protecting workers, electrical devices and wiring at a construction site. More particularly, the apparatus, systems and methods relate to a safety box that attaches to an electrical box and provides access to a switch or outlet inside the electrical box. Specifically, the apparatus, systems and methods provide for a safety box that attaches to an electrical box and allows for the activation of electricity at the electrical box and an electrical system at a construction site.

2. Description of Related Art

At a construction site, there are several different phases involved in completing the construction project. For example, early in the construction process, the project is framed. After the project is framed, the electrical wires are routed within the frame and electrical boxes are installed in the frame at termination points of the electrical wires. This is done early in the construction process because after insulation is installed in the framing and drywall is attached over the framing, it would be destructive to have to cut the drywall to install electrical boxes at a later time. Even though the electrical system wires and electrical boxes are installed early in the construction process, they cannot be activated or energized until much later in the construction process due to bare wire connections inside the electrical box. If one or more electrical boxes are energized before the boxes are covered with a cover plate, the Occupational Safety and Health Agency (OSHA) can fine the contractor of a jobsite for each electrical outlet that is energized without a cover plate. These fines can be rather expensive and with a large number of electrical outlets the total amount of the fine can add up quickly. What is needed is a better way of installing electrical boxes at a jobsite.

### SUMMARY OF THE INVENTION

The preferred embodiment of the invention includes an electrical safety box (e.g., electrical safety cover). The electrical safety box includes a box-shaped base and a cover. The box-shaped base can be easily attached to an electrical box in place of a cover plate that is normally attached to the electrical box. The box-shaped base allows for easy access to a light switch, or an outlet, or a combination of light switches and outlets inside the electrical box. The cover is attached to the box-shaped base and can be easily moved between open and closed positions. For example, the cover may be pivotally attached to the base to be swung between open and closed positions. The electrical safety box can be formed out of a single piece of plastic with the door attached to the base with a thin strip of plastic that can act as a hinge 17 that allows the door to be opened and closed. The electrical safety box can be formed with a bright material such as bright orange plastic so that electrical safety covers can be easily identified at a construction site. Electrical safety boxes can be formed in a variety of dimensions. For example, the electrical safety box can be formed to enclose and protect a single light switch, two light switches, three light switches, or a different number of light switches. Alternatively, the electrical safety box may be formed to protect a single light switch and one electrical outlet, two light switches and one or more electrical outlets, and so on.

The preferred embodiment of the invention may be configured as a method. The method begins by attaching electrical safety covers to electrical safety boxes. For example, the covers can be attached at a construction site to protect the electrical boxes and to make them Occupational Safety and Health (OSHA) compliant. As previously mentioned, when an electrical system at a construction site is OSHA compliant, the electrical system can be energized which allows the electrical system to be used by different construction crews at the construction site. The method provides for opening a door of the electrical safety cover to access the light switch or outlet protected by electrical safety cover and for closing the door when the outlet, electrical switch, or other device protected by the electrical safety cover is not being used. In some embodiments, the electrical safety cover can be removed from within an electrical box after a job at a jobsite has been completed and reattached to a different electrical box at a different jobsite.

### BRIEF DESCRIPTION OF SEVERAL VIEWS OF THE DRAWINGS

One or more preferred embodiments that illustrate the best mode(s) are set forth in the drawings and in the following description. The appended claims particularly and distinctly point out and set forth the invention.

The accompanying drawings, which are incorporated in and constitute a part of the specification, illustrate various example methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates a perspective view of a preferred embodiment of an electrical safety box.

FIG. 2 illustrates an exploded perspective view of the preferred embodiment of the electrical safety box before it is attached to an electrical box on a wall.

FIG. 3 illustrates an exploded perspective view of the preferred embodiment of the electrical safety box after it is attached to an electrical box on a wall.

FIG. 4 illustrates a perspective view of the preferred embodiment of the electrical safety box attached to an electrical box on a wall and surrounded by drywall.

FIG. 5 illustrates a perspective view of an electrical box before the electrical safety box is attached to the electrical box.

FIG. 6 illustrates a front view of the preferred embodiment of the electrical safety box configured to protect a light switch.

FIG. 7 illustrates a front view of the preferred embodiment of the electrical safety box configured to protect two electrical outlets.

FIG. 8 illustrates a front view of the preferred embodiment of the electrical safety box configured to protect ground fault interrupt (GFI) switch.

FIG. 9 illustrates an embodiment of a method for using an electrical protection box.

Similar numbers refer to similar parts throughout the drawings.

### DETAILED DESCRIPTION OF THE INVENTION

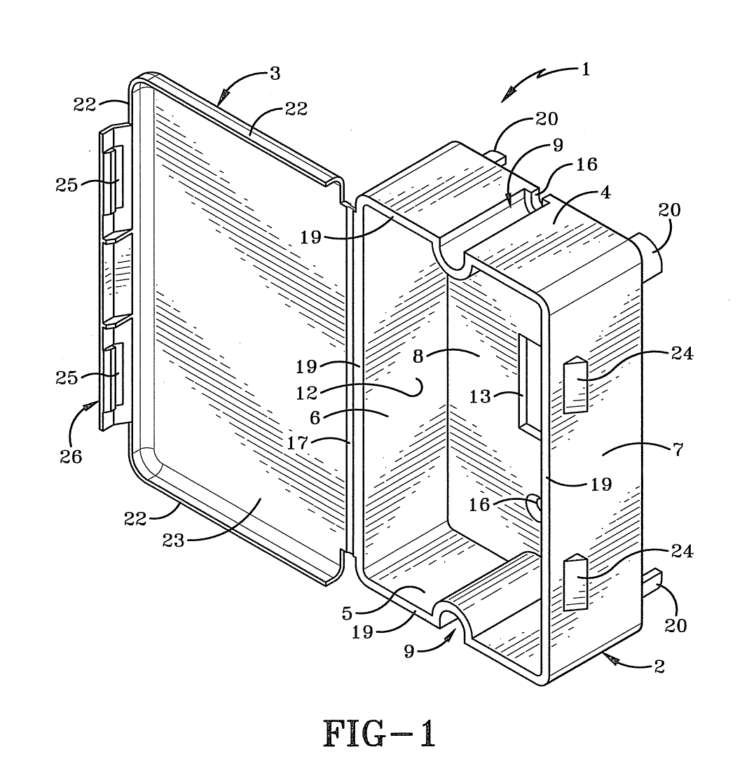

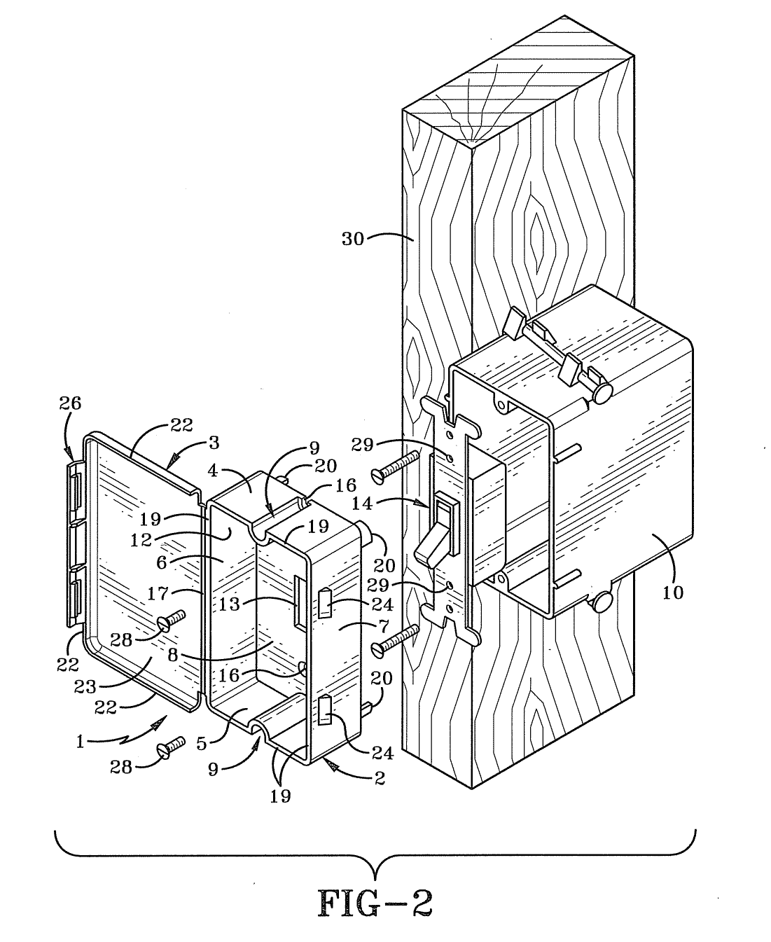

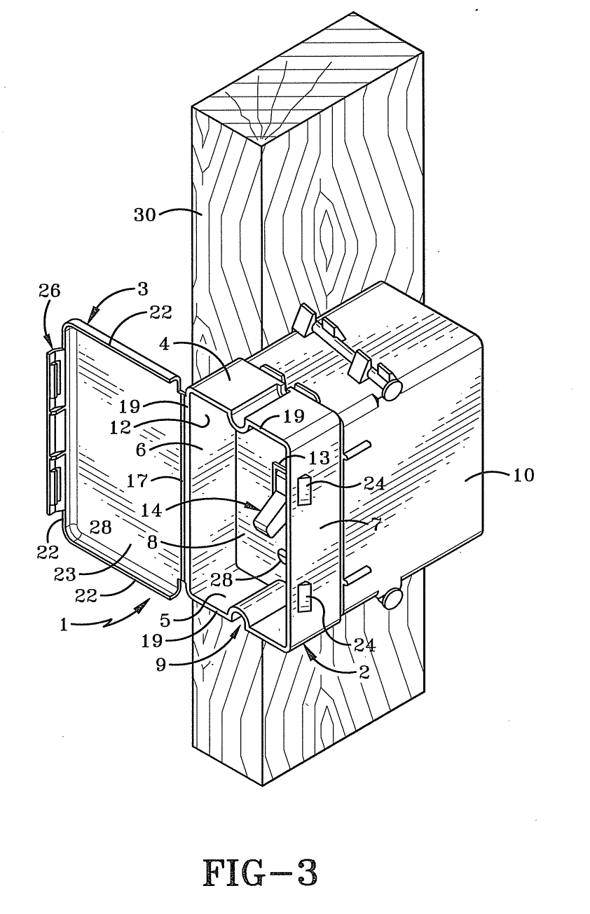

FIG. 1 illustrates a preferred embodiment of an electrical safety cover 1. The electrical safety cover 1 includes a base 2, a cover door 3, and is easily attached to an electrical device installed in an electrical box 10 (shown in FIG. 3) that is installed at a jobsite. The electrical safety cover 1 is configured to cover terminating ends of wires and other metallic connection devices that are carrying electricity. The electrical safety cover 1 still allows for access to switches and outlets at a jobsite while the jobsite is under construction while protecting electrical terminal connections inside an electrical box 10. This allows for more construction trades to use an energized electrical system than when the electrical system is traditionally activated near the end of a construction project. As previously mentioned, in the past the electrical system was installed early in the construction cycle after framing but the system could not be energized due to the exposure of electrical connections within electrical boxes 10. Each electrical connection could lead to a fine by Occupational Safety and Health Agency (OSHA) and with many electrical boxes these fines could be substantial. However, because the electrical safety box 1 encloses these connection points, the electrical system can be safely energized after it is installed without being subject to injury to workers and safety fines from OSHA.

The box-shaped base 2 includes a top wall 4, a bottom wall 5, a left wall 6, and a right wall 7. These walls are generally rectangular-shaped and form a rectangular perimeter that matches the perimeter of an electrical box 10 the electrical safety cover 1 is to be attached to. The walls 4, 5, 6, and 7 are generally short enough in height to allow for the installation of drywall 32 over and around the electrical safety cover 1. In one configuration of the preferred embodiment, the top wall 4 and bottom wall 5 can be formed with semicircular regions 9 with holes 16 that allow access to screw holes on a GFI outlet devices that is attached the electrical box 10.

The base 2 and cover door 3 of the electrical safety cover 1 are generally formed out of plastic or another polymer; however, other materials can be used. For example, the electrical safety cover 1 can be formed out of a polypropylene material, also known as polypropene, that is a thermoplastic polymer. Polypropylene is an addition polymer made from the monomer propylene. It is rugged and unusually resistant to many chemical solvents, bases and acids. The electrical safety cover 1 can be molded from heated polypropylene into the shape of the safety cover 1. Polypropylene polymers can be oxidized at high temperatures; therefore, anti-oxidants can be added to prevent polymer degradation to ensure that the electrical safety cover 1 is sufficiently strong, resistant to fire and OSHA compliant.

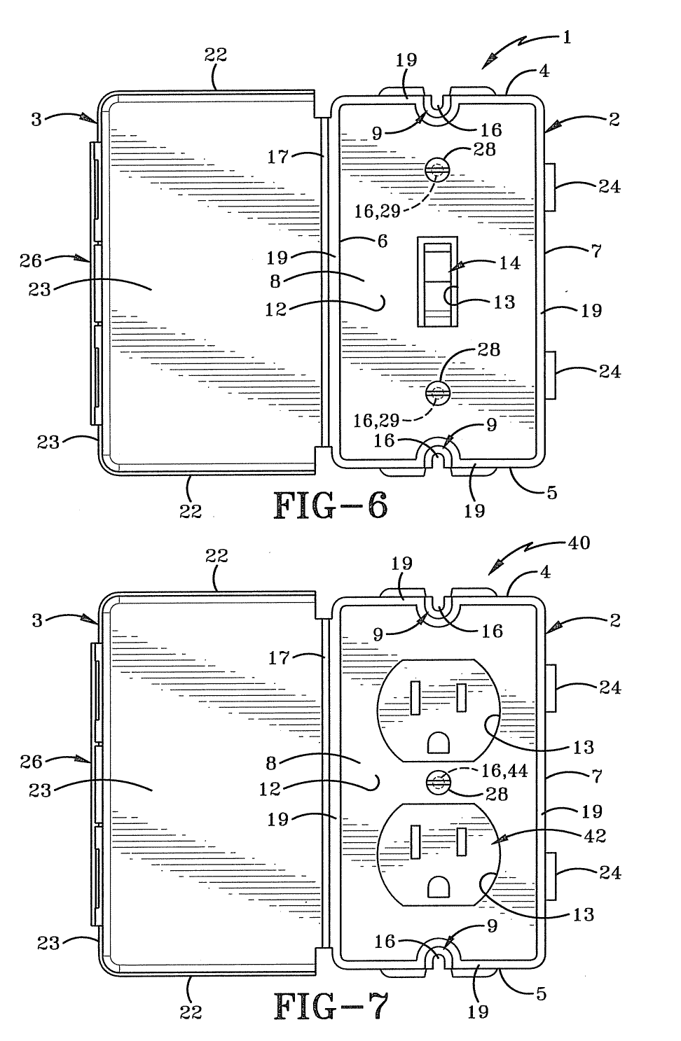

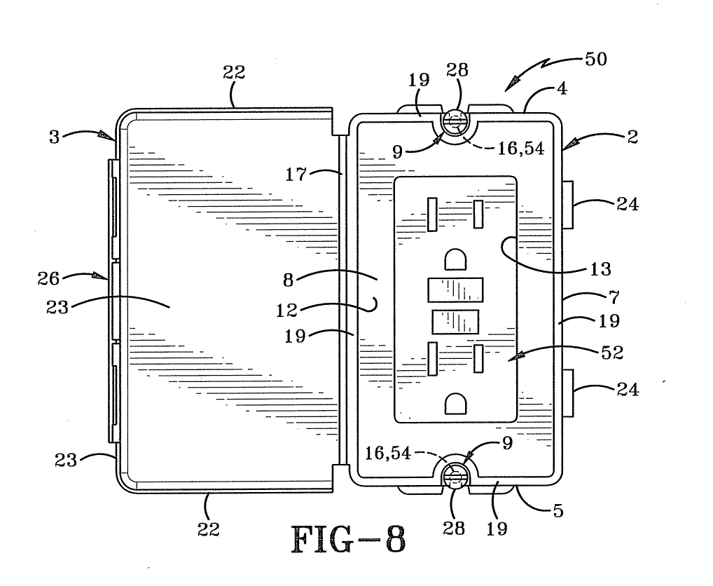

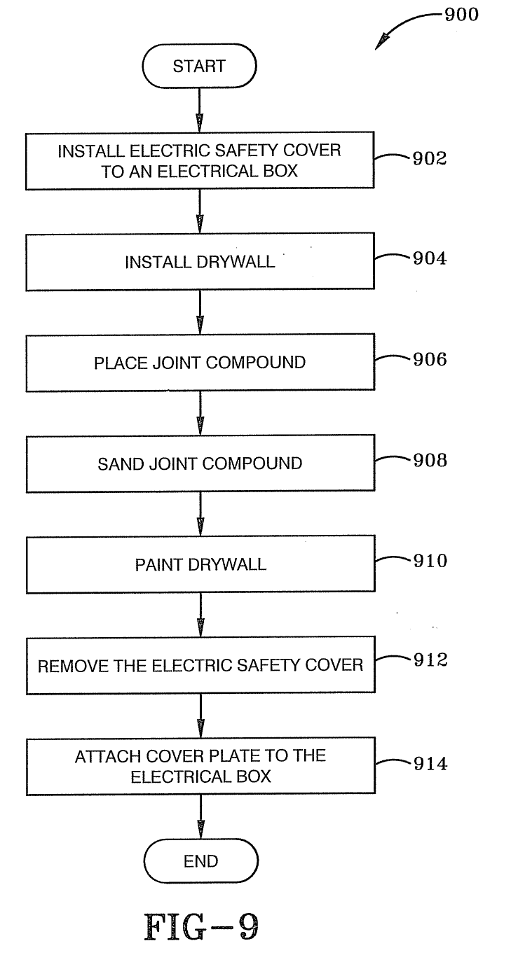

The base 2 is also formed with a back wall 8. The back wall 8 and the side walls 4, 5, 6, and 7 form a chamber 12. The back wall 8 is formed with an opening 13 to allow a switch 14 (shown in FIG. 6) to protrude through the opening 13 into the chamber 12. The back wall 8 can also be formed with one or more openings 16 to allow the back wall 8 to be fastened to a device such as a switch or an outlet that is attached to the electrical box 10 through the one or more openings 16. For example, FIG. 6 illustrates an electrical safety cover 1 with upper and lower holes 29 that allow the electrical safety cover 1 to be attached to a switch mounted in the electrical box 10. FIG. 7 that illustrates an electrical safety cover 1 with a center hole 44 that allows the electrical safety cover 1 to be attached to an electrical socket device mounted in the electrical box 10. For example, FIG. 8 illustrates an electrical safety cover 1 mounted to a GFI socket in the electrical box 10 with bolts 28 passing through holes 54 in the semicircular upper and lower regions 9.

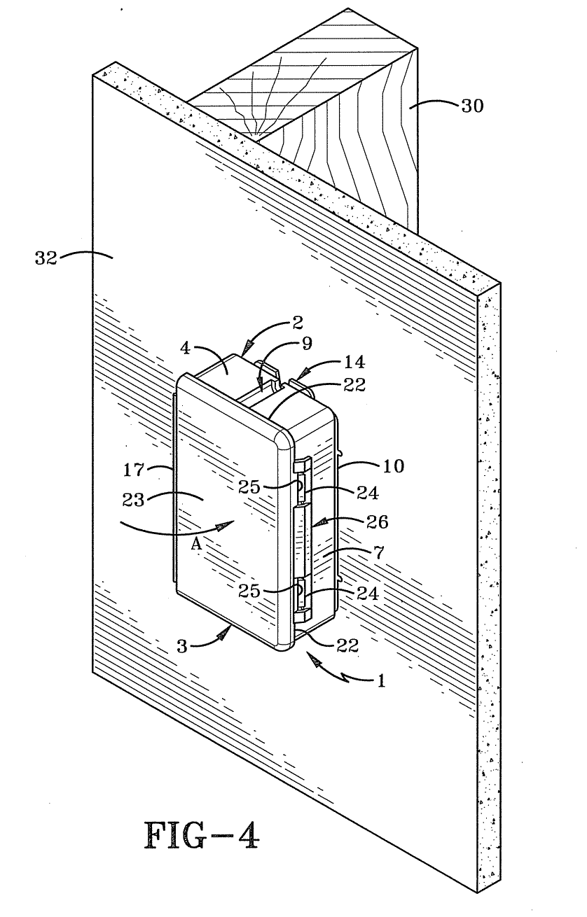

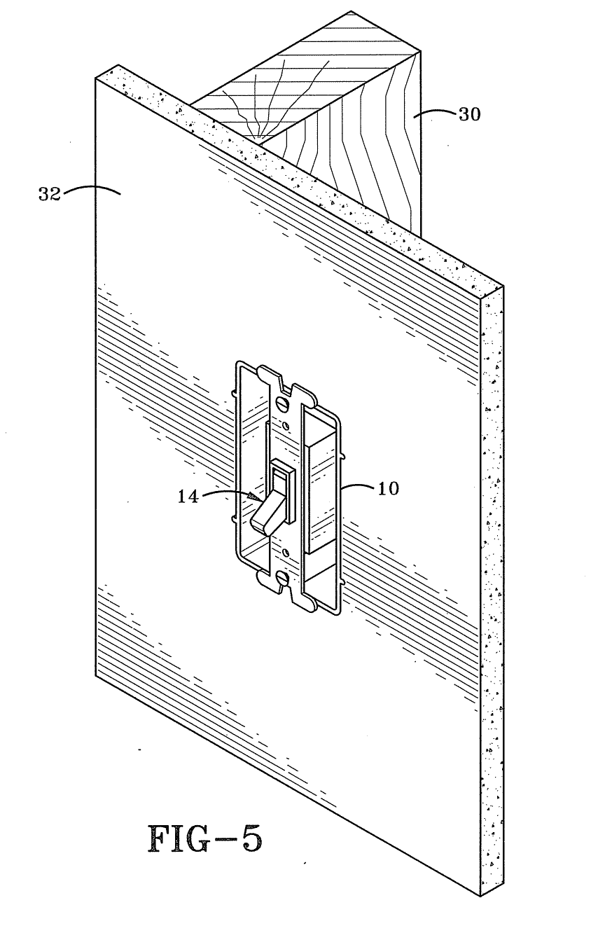

The cover door 3 can be formed with one or more lips 22 on the front wall 23 of the cover so that when the cover door 3 is in the closed position the lips 22 curve around the front edges 19 of the base 2. When the cover door 3 is move to the closed position in the direction of arrow A (FIG. 4), the lips 22 will prevent dirt and dust from entering the chamber 12. In the preferred embodiment, the cover door 3 includes a latch member 26. The latch member 26 may be formed out of the same plastic polymer or other material as the cover door 3 and may be thin enough so that it may be flexible. One or more locking tabs 24 may be formed on the right wall 7 of the base 2. As the cover door 3 is moved to the closed position, the latch member 26 is slid over the locking tabs 24 so that the latch member 26 is clipped around the locking tabs 24. This ensures that the electrical safety cover 1 will remain in the closed position until force is used to pull the latch member 26 away from the locking tabs 24 to open the electrical safety cover 1.

The electrical safety cover 1 can include other useful features and objects. For example, the back wall 8 of the base 2 may include one or more alignment guides 20 that project backward toward the electrical box 10. These alignment guides can be used to guide the electrical safety cover 1 onto the electrical box 10. The electrical safety cover 1 can protect a wide variety of electrical boxes mounted with a variety of electrical devices. For example, electrical safety cover 1 can be configured to protect an electrical box mounted with two, four, six, or another member of electrical sockets or light switches. Alternatively the electrical cover 1 can be configured to protect any combination of switches, outlets, GFI outlets or another type of electrical device mounted in an electrical box.

Having described the structure of the preferred embodiment of the electrical safety cover 1 in detail, we will now describe its use as illustrated by method 900 of FIG. 9. Example methods of use may be better appreciated with reference to flow diagrams. While for purposes of simplicity of explanation, the illustrated methodologies are shown and described as a series of blocks; it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

The method 900 of using electrical safety covers begins by installing an electrical safety cover to an electrical box, at 902. As previously mentioned, the electrical wiring and electrical boxes are where electrical connections are made and installed after the framing stage at construction sites. By installing electrical safety covers over the electrical boxes the electrical system can now be powered up and used by other trades at the job construction site rather than needing to wait until near the end of a construction project when drywall has been installed before powering up the electrical system.

Because the electrical safety covers have similar dimensions to the electrical boxes that they are protecting, drywall may be installed or placed around the electrical safety covers, at 904. This in turn allows the placement of joint compound around the electrical safety covers and in other places on the drywall, at 906. The joint compound and drywall may be sanded, at 908, while electrical safety covers protect the electrical boxes and like trickle devices mounted in the boxes from sanding dust and other debris. Later, the drywall can be painted at 910. When all needed painting and construction has been completed, the electrical safety covers can be removed, at 912. Finally, traditional cover plates are attached to the remaining electrical boxes, at 914.

In the foregoing description, certain terms have been used for brevity, clearness, and understanding. No unnecessary limitations are to be implied therefrom beyond the requirement of the prior art because such terms are used for descriptive purposes and are intended to be broadly construed. Therefore, the invention is not limited to the specific details, the representative embodiments, and illustrative examples shown and described. Thus, this application is intended to embrace alterations, modifications, and variations that fall within the scope of the appended claims.

Moreover, the description and illustration of the invention is an example and the invention is not limited to the exact details shown or described. References to “the preferred embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in the preferred embodiment” does not necessarily refer to the same embodiment, though it may.

What is claimed is:

1. An electrical safety cover comprising:
a safety box adapted to be attached to an electrical box including:
a base with a hole adapted to allow access to an electrical device covered by the safety box;
a plurality of walls extending outwardly from the base forming a chamber adapted to allow access to the electrical device when the safety box is attached to the electrical box; and
an access cover adapted to be moved between open and closed positions, wherein the open position allows access to the electrical device, wherein the closed position protects the electrical box while the electrical safety cover is attached to the electrical box at a job site.

2. The electrical safety cover of claim 1 wherein the plurality of walls extend outward from the base and through drywall when drywall is placed around the electrical safety cover.

3. The electrical safety cover of claim 1 wherein the electrical safety cover is Occupational Safety and Health (OSHA) compliant to allow the electrical device to be electrically energized before drywall is placed around the electrical box.

4. The electrical safety cover of claim 1 wherein the access cover is flexibly attached to the safety box.

5. The electrical safety cover of claim 1 wherein the safety box is adapted to be attached to the electrical box with one or more screws.

6. The electrical safety cover of claim 1 wherein the safety box further comprises:
a top side wall;
a left side wall;
right side wall;
a bottom side wall;
a back wall with at least one hole to provide access to the electrical box; and
wherein top wall, right side wall, left side wall, bottom side wall and back wall form a box structure.

7. The electrical safety cover of claim 6 wherein the top side wall and bottom side wall have elongated U-shaped channels providing access to screw holes in the electrical box.

8. The electrical safety cover of claim 1 further comprising:
a locking protrusion extending outwardly from one of the plurality of walls;
a flexible locking tab, wherein the access cover further comprises:
a right edge, a left edge, a top edge, and a bottom edge forming a rectangular planar surface; and
wherein the flexible locking tab is on the right edge of the access cover and is adapted to bend over the locking protrusion to lock the access cover in a closed position.

9. In combination:
an electrical box for housing an electrical device inside a building structure; and
an electrical safety cover adapted to be attached to the electrical box allowing access to an electrical device housed in the electrical device before drywall has been installed around the electrical box.

10. The combination of claim 9 wherein the electrical safety cover is adapted to be attached to the electrical box by screwing one or more screws into the one of more standard screw holes on the electrical box.

11. The combination of claim 9 wherein the standard screw holes on the electrical box are axially aligned with screw holes on the electrical safety cover.

12. The combination of claim 9 wherein the electrical safety cover further comprises:
a base with a hole adapted to allow access to the electrical device;
a plurality of walls extending outwardly from the base forming a chamber adapted to allow access to the electrical device when the electrical safety box is attached to the electrical box; and
an access cover adapted to be moved between open and closed positions, wherein the open position allows access to the electrical device, and wherein the closed position protects the electrical box while the electrical safety cover is attached to the electrical box at a job site.

13. The combination of claim 9 where the electrical safety cover further comprises:
a safety door for closing and preventing access to the electrical box.

14. The combination of claim 9 wherein the electrical device in the electrical box is one or more of the group of: a control, a switch and an outlet.

15. A method for energizing an electrical box at a construction site early in the construction phase before drywall has been hung comprising:
installing an electrical safety cover over an electrical box so the exposed metal areas carrying electricity are covered; and
energizing an electrical circuit associated with the electrical box so that the electrical circuit is functional before drywall has been placed around the electrical box.

16. The method for energizing an electrical box at a construction site early in the construction phase of claim 15 further comprising:
turning on a switch inside the electrical safety cover that activates an electrical device.

17. The method for energizing an electrical box at a construction site early in the construction phase of claim 15 further comprising:
opening an access door of the electrical safety cover protecting the electrical box; and
plugging an electrical device into an electrical socket inside the electrical box.

18. The method for energizing an electrical box at a construction site early in the construction phase of claim 15 further comprising:
installing drywall around the electrical safety cover.

19. The method for energizing an electrical box at a construction site early in the construction phase of claim 15 wherein the installing an electrical safety cover over an electrical box further comprises:
attaching the electrical safety cover to the electrical box with screws.

20. The method for energizing an electrical box at a construction site early in the construction phase of claim 15 further comprising:
removing the electrical safety cover after drywall has been placed about the electrical box and finished; and
attaching a cover plate to the electrical box after the electrical safety cover has been removed.
